(19) United States
(12) Patent Application Publication
(10) Pub. No.: US 2014/0209995 A1
(43) Pub. Date: Jul. 31, 2014

(54) Non-Volatile Memory Cells Having Carbon Impurities and Related Manufacturing Methods

(71) Applicants: Cheong Min Hong, Austin, TX (US); Sung-Taeg Kang, Austin, TX (US)

(72) Inventors: Cheong Min Hong, Austin, TX (US); Sung-Taeg Kang, Austin, TX (US)

(21) Appl. No.: 13/753,047

(22) Filed: Jan. 29, 2013

(51) Int. Cl. H01L 29/792; H01L 29/66

(52) U.S. Cl. CPC H01L 29/792; H01L 29/66833
USPC 257/325; 438/287

(57) ABSTRACT

Non-volatile memory (NVM) cells having carbon impurities are disclosed along with related manufacturing methods. The carbon impurities can be introduced using a variety of techniques, including through epitaxial growth of silicon-carbon (SiC) layers and/or carbon implants. Further, the carbon impurities can be introduced into one or more structures within NVM cells, including source regions, drain regions, gate regions, and/or charge storage layers. For discrete charge storage layers that utilize nanocrystal structures, carbon impurities can be introduced into the nanocrystal charge storage layers. The disclosed embodiments are useful for a variety of NVM cell types including split-gate NVM cells, floating gate NVM cells, discrete charge storage NVM cells, and/or other desired NVM cells. Advantageously, the carbon impurities introduce tensile stress into the cell structures, and this tensile stress helps maintain NVM system performance and data retention even as device geometries are reduced.

### TECHNICAL FIELD

This disclosure relates generally to non-volatile memory (NVM) systems, and more specifically, to methods for making NVM cells.

### BACKGROUND

Prior programmable memories have been implemented using non-volatile memory (NVM) cells. Certain NVM cells are implemented using thin film storage (TFS) technologies and charge storage layers that rely upon electron tunneling. While it is desirable to shrink device geometries for such NVM cells, reducing tunnel oxide thickness for these NVM cells is difficult because of data retention issues. For certain applications, inadequate data retention margin is not acceptable. As such, it has become difficult to scale down TFS-based NVM systems for these applications.

One prior solution to this difficulty in scaling is to improve tunnel oxide leakage current, thereby improving data retention, by changing barrier heights of tunnel oxide layers within NVM cells to introduce longitudinal tensile stress. Another prior solution is to improve data retention by introducing a tensile stress within an etch stop layer for an NVM cell.

### DESCRIPTION OF THE DRAWINGS

It is noted that the appended figures illustrate only example embodiments and are, therefore, not to be considered as limiting the scope of the present invention. Elements in the figures are illustrated for simplicity and clarity and have not necessarily been drawn to scale

FIG. 1 is a cross-section diagram of an embodiment for a split-gate NVM cell stack after formation of the select gate (SG).

FIGS. 2 is a cross-section diagram of an embodiment after a charge storage layer has been formed that includes a carbon impurity (C_{IMPURITY}).

FIG. 3 is a cross-section diagram of an embodiment having a completed dielectric layer that includes an embedded charge storage layer.

FIG. 4 is a cross-section diagram of an embodiment after a control gate (CG) has been formed that includes a carbon impurity (C_{IMPURITY}).

FIG. 5 is a cross-section diagram of an embodiment after the select gate (SG) and the control gate (CG) have been patterned and etched.

FIG. 6 is a cross-section diagram of an embodiment after drain/source regions and spacers have been formed.

FIG. 7 is a cross-section diagram of an embodiment for a carbon impurity (C_{IMPURITY}) being introduced into drain and source regions.

FIG. 8 is a cross-section diagram of an embodiment for a completed split-gate NVM cell stack including carbon impurities (C_{IMPURITY}) within one or more cell structures.

FIG. 9 is a cross-section diagram of an embodiment for a completed split-gate NVM cell stack that includes metal silicide regions.

FIG. 10 is a diagram of an embodiment for wordline driver and column driver connections associated with a split-gate NVM cell having carbon impurities (C_{IMPURITY}), as described herein.

FIG. 11 is a block diagram of an embodiment for a split-gate NVM system including an array of split-gate NVM cells.

### DETAILED DESCRIPTION

Non-volatile memory (NVM) cells having carbon impurities are disclosed along with related manufacturing methods. The carbon impurities can be introduced using a variety of techniques, including through epitaxial growth of silicon-carbon (SiC) layers and/or carbon implants. Further, the carbon impurities can be introduced into one or more structures within NVM cells, including source regions, drain regions, gate regions, and/or charge storage layers. For discrete charge storage layers that utilize nanocrystal structures, carbon impurities can be introduced into the nanocrystal charge storage layers. The disclosed embodiments are useful for a variety of NVM cell types including split-gate NVM cells, floating gate NVM cells, discrete charge storage NVM cells, and/or other desired NVM cells. Advantageously, the carbon impurities introduce tensile stress into the cell structures, and this tensile stress helps maintain NVM system performance and data retention even as device geometries are reduced. Different features and variations can be implemented, as desired, and related or modified systems and methods can be utilized, as well.

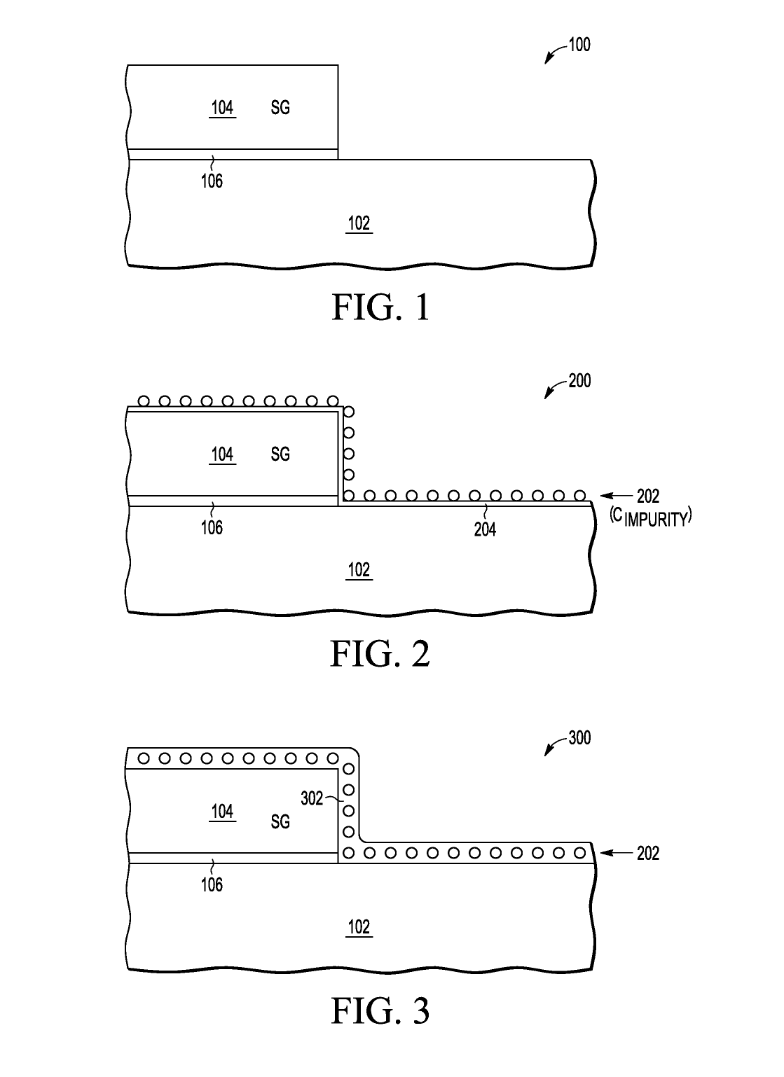

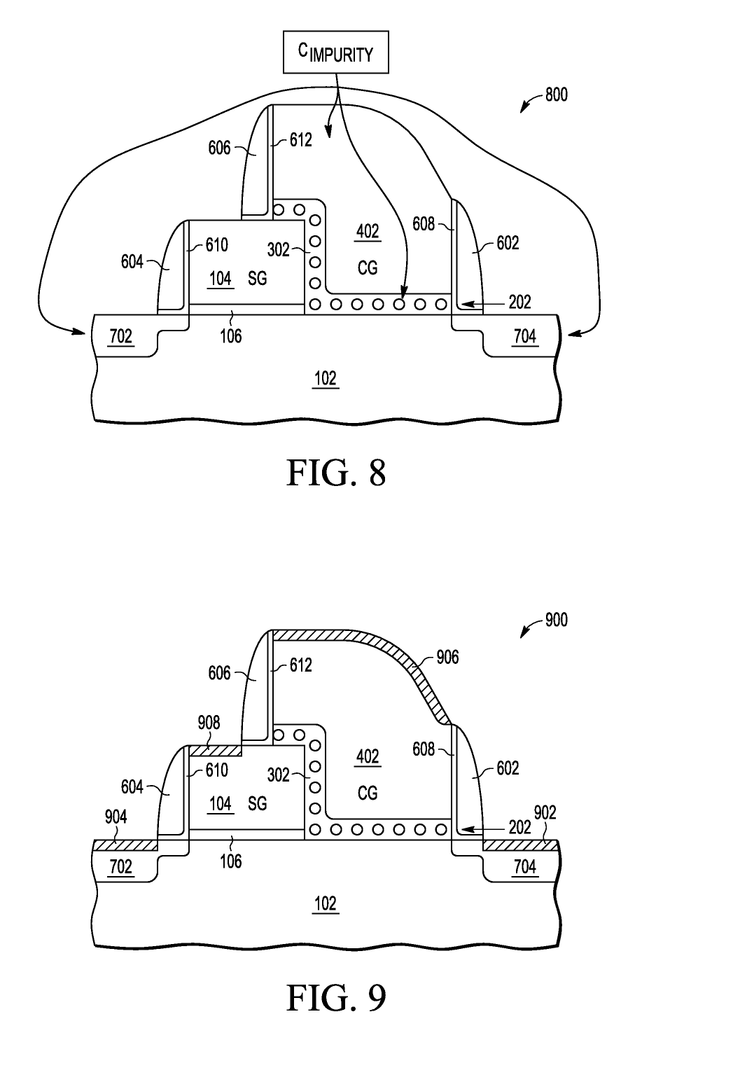

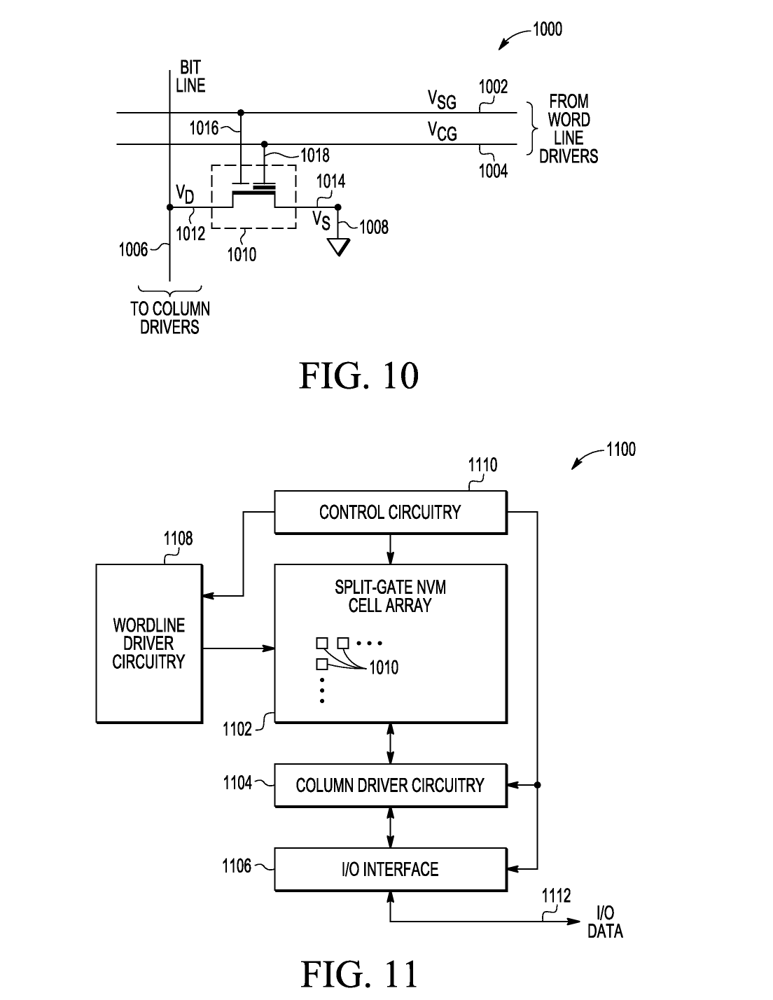

FIGS. 1-7 provide process steps for forming NVM cell stacks having carbon impurities (C_{IMPURITY}). FIGS. 8-9 provide examples of completed NVM cell stacks. FIGS. 10-11 provide memory system embodiments having NVM memory cells in which carbon impurities (C_{IMPURITY}) have been introduced, as described herein. Advantageously, the embodiments described herein improve data retention while maintaining tunnel oxide thickness and/or allow scaling down of tunnel oxide thickness while maintaining data retention.

FIG. 1 is a cross-section diagram of an embodiment 100 for a split-gate NVM cell stack after formation of the select gate (SG) 104. As depicted, the select gate (SG) 104 has been formed over a select gate dielectric layer 106 that in turn has previously been formed on top of semiconductor substrate 102. It is noted that the select gate (SG) 104 can be formed, for example, using a polysilicon deposition processing step to form conductive doped polysilicon. The select gate 104 can be formed using other conductive materials, if desired. It is further noted that the select-gate dielectric layer 106 may be an oxide layer, for example, that is grown or deposited on top of the substrate 102. Other dielectric materials could also be used as the dielectric layer 106, if desired.

It is noted that the semiconductor substrate 102 described herein can be any desired semiconductor material or combinations of materials, such as gallium arsenide, silicon germanium, silicon, monocrystalline silicon, other semiconductor materials, and combinations of these semiconductor materials. It is also noted that the semiconductor substrate 102 represents the top portion of a semiconductor substrate. It is further noted that the semiconductor substrate 102 described herein could be formed on top of other substrate materials including a separate non-semiconductor material, if desired, such as thin film semiconductor substrates formed on other semiconductor or non-semiconductor materials. Further, it is noted that while split-gate NVM cells are shown, other NVM cell types could also be utilized, such as floating gate NVM cells, other discrete charge storage NVM cells, and/or other desired NVM cells. Further variations could also be implemented, as desired.

FIGS. 2 is a cross-section diagram of an embodiment 200 after a charge storage layer 202 has been formed that includes a carbon impurity (C_{IMPURITY}). The charge storage layer 202 depicted has been formed on top of an initial tunnel oxide layer 204, which has been previously formed on top of substrate 102 and select gate (SG) 104. It is noted that the initial tunnel oxide layer 204 can be formed using a rapid thermal oxidation technique, for example, that utilizes in situ steam generation (ISSG) processing to form the oxide layer. The charge storage layer 202 can be formed, for example, using silicon nanocrystals, metal nanoclusters, nitride or some other desired discrete charge storage material. It is further noted that the charge storage layer can also be a continuous charge storage layer, if desired, such as a floating gate charge storage layer formed using polysilicon layers, oxide-nitride-oxide layers, or layers of other desired materials. Other charge storage layers could also be used for, if desired.

As described herein, a carbon impurity (C_{IMPURITY}) can be introduced into the charge storage layer 202 to improve NVM cell performance. For example, where silicon nanocrystals are used to form a discrete charge storage layer, a nanocrystal deposition step can be used to form the charge storage layer 202. One nanocrystal deposition process that can be utilized is a silicon-carbon (SiC) deposition step to cause epitaxial growth of silicon nanocrystals with a desired carbon impurity level. The resulting growth can be, for example, between about 150 to 350 Angstroms, if desired. Further, for this epitaxial growth step, the impurity level of carbon (C) atoms can be 0.5% to 3.0% of the silicon-carbon (SiC) layer. As a further example, a carbon impurity level of 1% (e.g., Si_{0.99}C_{0.01}) could be used, if desired. Another nanocrystal deposition process that can be utilized is first to deposit a silicon layer using a rapid thermal chemical vapor deposition (RTCVD) process. This silicon layer can be, for example, between about 150 to 350 Angstroms, if desired. Next, a carbon implant processing step can be used to introduce carbon impurities into the deposited silicon layer. This carbon implant can use, for example, a density of carbon ions per square centimeter of about 5×10¹⁴ cm⁻² to 5×10¹⁶ cm⁻². This carbon implant can be configured to achieve a carbon impurity level of about 0.5% to 3.0% of the resulting silicon-carbon (SiC) layer. As a further example, a carbon impurity level of 1% (e.g., Si_{0.09}C_{0.01}) could be used, if desired. Other implant densities, impurity levels, and layer thicknesses could also be utilized, as desired and additional variations could be implemented, as desired. Further, it is noted that additional and/or different processing steps could be used to introduce the carbon impurities (C_{IMPURITY}) into the charge storage layer, if desired.

FIG. 3 is a cross-section diagram of an embodiment 300 after a dielectric layer has been completed with an embedded charge storage layer 202. To complete the formation of the dielectric layer 302, a second oxide layer can be deposited or formed over the charge storage layer 202. The second oxide layer and the initial tunnel oxide 204 together form the dielectric layer 302 with the embedded charge storage layer 202. It is noted that the second oxide layer can be formed using a high temperature oxide (HTO) deposition processing step. For example, a RTCVD HTO deposition step can be conducted along with an in situ rapid thermal processing (RTP) anneal, if desired. It is further noted that additional anneal steps can also be performed, if desired. For example, a nitrous oxide (N₂O) anneal and/or an oxygen (O₂) RTP anneal can be utilized, if desired. Additional or different processing steps could also be utilized, as desired.

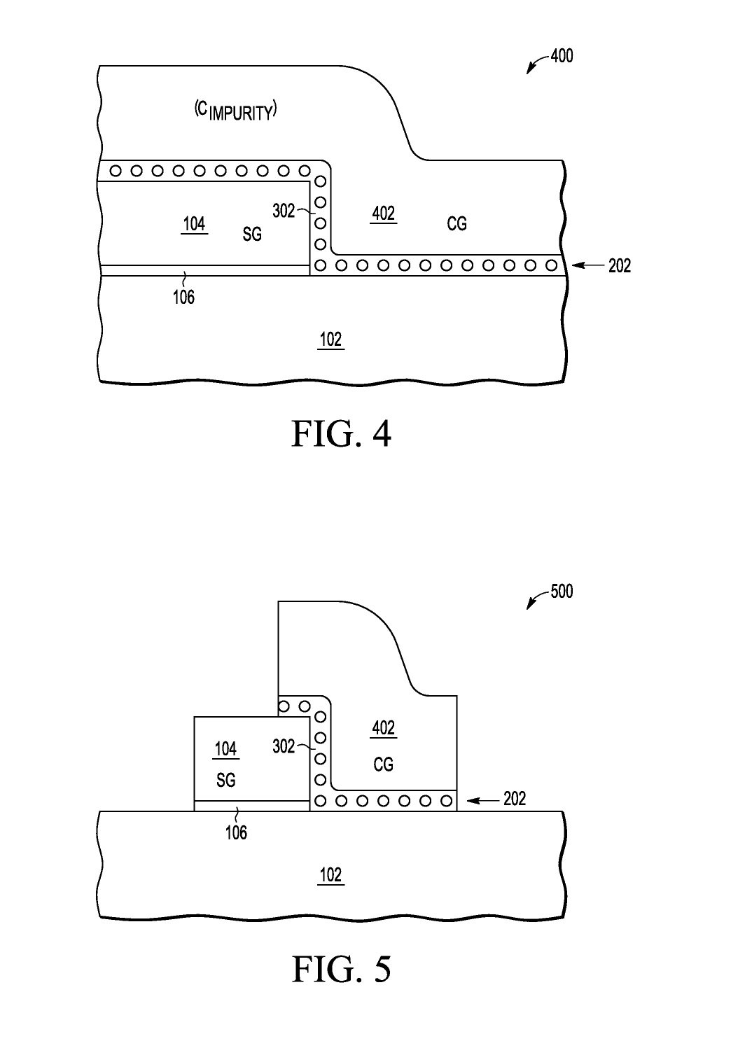

FIG. 4 is a cross-section diagram of an embodiment 400 after a control gate (CG) 402 has been formed that includes carbon impurities (C_{IMPURITY}). The control gate (CG) 402 can be formed over the dielectric layer 302, for example, by depositing a conductive doped polysilicon layer while introducing a carbon impurity. For example, a deposition processing step can be used to form an epitaxial silicon growth including a carbon impurity. The epitaxial growth can be, for example, between about 500 to 1500 Angstroms, if desired. The carbon impurity can be an impurity level of 0.5% to 3.0% of the silicon-carbon (SiC) layer. As a further example, a carbon impurity level of 1% (e.g., Si_{0.99}C_{0.01}) could be used, if desired. Other impurity levels and layer thicknesses could also be utilized, as desired. Further, it is noted that additional and/or different processing steps could be used to introduce the carbon impurities (C_{IMPURITY}) into the control gate region, if desired.

FIG. 5 is a cross-section diagram of an embodiment 500 after the select gate (SG) 102 and the control gate (CG) 402 have been patterned and etched. After etching, a small portion of the control gate (CG) 402 remains over the select gate (SG) 102. Further, select gate (SG) 102 and the control gate (CG) 402 have been patterned and etched so that the substrate 102 is exposed adjacent the select gate (SG) 102 and the control gate (CG) 402.

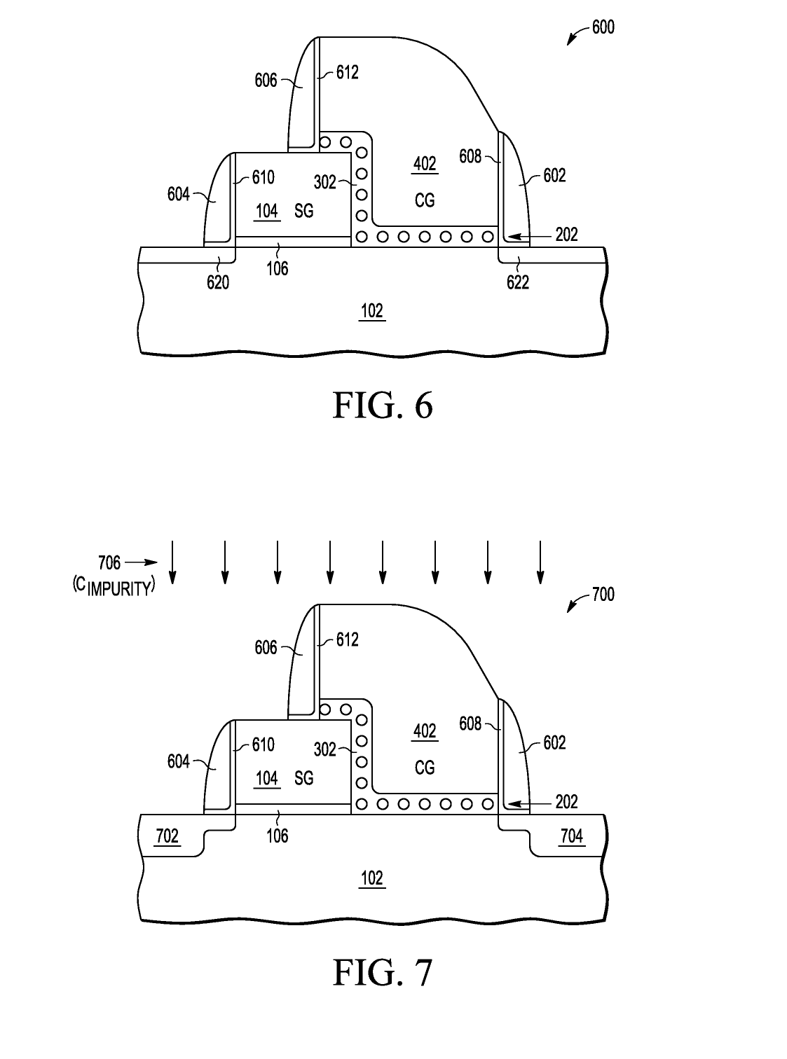

FIG. 6 is a cross-section diagram of an embodiment 600 after source/drain regions and spacers have been have been formed. As depicted, lightly-doped drain region 620 and lightly-doped source region 622 have been formed, for example, using an LDD (lightly doped drain) processing step. In addition, spacers 602, 604, and 606 have also been formed, as well as protective oxide layers 608, 610, and 612. The spacers 602, 604, and 606 can be implemented as nitride spacers, a combination of nitride and oxide spacers, or as spacers from other material, as desired. It is noted that the spacers can be patterned, deposited, and etched as desired. Variations could be implemented, as desired.

FIG. 7 is a cross-section diagram of an embodiment 700 for a carbon impurity (C_{IMPURITY}) being introduced into drain and source regions. As depicted, drain region 702 and source region 704 have been more heavily doped and extended further into substrate 102, for example, through an additional ion implant processing step. As part of this implant processing step and/or using an additional processing implant step, a carbon impurity (C_{IMPURITY}) can be introduced into one or more of these regions, as desired. For example, a carbon implant processing step can be performed to introduce a carbon impurity (C_{IMPURITY}) into the drain region 702 and/or the source region 704. Further, the carbon implant can use, for example, a density of carbon ions per square centimeter of about 5×10¹⁴ cm⁻² to 5×10¹⁶ cm⁻². This carbon implant can be configured to achieve an impurity level of 0.5% to 3.0% of the silicon-carbon (SiC) layer. As a further example, a carbon impurity level of 1% (e.g., Si_{0.99}C_{0.01}) can be utilized, if desired. Other implant densities, impurity levels, and layer thicknesses could also be utilized, as desired. Further, it is noted that additional and/or different processing steps could be used to introduce the carbon impurities (C_{IMPURITY}) into the source/drain regions, if desired.

FIG. 8 is a cross-section diagram of an embodiment 800 for a completed split-gate NVM cell stack. As described herein, the completed split-gate NVM stack includes carbon impurities (C_{IMPURITY}) in one or more of the drain region 702, source region 704, control gate (CG) 402, and/or the charge storage layer 202. It is again noted that the carbon impurities (C_{IMPURITY}) can be utilized in one of these structures or in a plurality of these structures, as desired. Further, carbon impurities (C_{IMPURITY}) could be included within any combination of these structures, as desired. In addition, carbon impurities (C_{IMPURITY}) could be included in other structures, if desired, such as within the select gate (SG) 102.

FIG. 9 is a cross-section diagram of an embodiment 900 for a completed split-gate NVM cell stack that includes metal silicide regions. In particular, for the embodiment 900 depicted, metal silicide regions have been added to the source 702, drain 704, select gate (SG) 102, and control gate (CG) 402. In particular, a metal silicide region 904 has been formed within the drain 702. A metal silicide region 902 has been formed within the source region 704. A metal silicide region 906 has been added to control gate (CG) 402. And a metal silicide region 908 has been added to the select gate (SG) 102.

It is noted that metal silicide regions can be formed, for example, by first forming a thin metal film over regions where metal silicide regions are desired. The thin metal film is then reacted with these regions through a series of annealing processes to form metal silicide regions. When heated, the thin metal film will react with exposed silicon within the interested regions to form a low-resistance metal silicide. This low-resistance metal silicide can be used to reduce resistance for electrical contacts and to reduce resistance for signal paths, such as polysilicon signal paths. Once the desired metal silicide regions are formed, the remaining metal film can then be removed by one or more etching processes. The formation of the metal silicide regions can also be a self-aligned process that uses already formed structures to align the formation of the metal silicide regions. Such self-aligned metal silicide regions are often called salicide, and the process of forming salicide regions is often called salicidation. A variety of metals can be used to form the metal silicide regions, including the following transition metals: titanium, cobalt, nickel, platinum or tungsten. Other metals could also be used, and different processing steps could also be used to form the metal silicide regions, as desired.

FIG. 10 is a diagram of an embodiment 1000 for wordline driver and column driver connections associated with a split-gate NVM cell 1010 having carbon impurities (C_{IMPURITY}), as described herein. For the embodiment depicted, a source voltage (V_{S}) 1014 is provided by a connection to ground 1008. A drain voltage (V_{D}) 1012 is provided by a connection to the column bit-line 1006, which is in turn coupled to column driver circuitry. A control gate voltage (V_{CO}) is provided by a connection to a first wordline 1004, and the select-gate voltage (V_{SG}) is provided by a connection to a second wordline 1002. The wordline 1002 and wordline 1004 are coupled to wordline driver circuitry.

FIG. 11 is a block diagram of an embodiment for a split-gate NVM system 1100 including a memory cell array 1102 having a plurality of split-gate NVM cells 1110, each having carbon impurities (C_{IMPURITY}), as described herein. The split-gate NVM cell array 1102 is coupled to wordline (WL) driver circuitry 1108, which provides select-gate and control-gate wordline voltages to the split-gate NVM cells 1110 within the memory cell array 1102. The split-gate NVM cell array 1102 is also coupled to column driver circuitry 1104. For read and verify operations, the column driver circuitry 1104 determines charge levels stored in selected NVM cells within the array 1102 and outputs related data to an input/output (I/O) interface 1106. For program and erase operations, the column driver circuitry 1104 provides program/erase voltage levels to selected NVM cells within the array 1102. Control circuitry 1110 provides control signals to the wordline (WL) driver circuitry 1108, the column driver circuitry 1104, the NVM cell array 1102, and the I/O interface 1106. It is further noted that the array of split-gate NVM cells 1102, the wordline driver circuitry 1108, the column driver circuitry 1104, the control circuitry 1110, and/or the I/O interface 1106 can be integrated within a single integrated circuit. It is further noted that the input/output (I/O) output data channel 1112 coupled to the I/O interface 1106 can be used internally within an integrated circuit or can be used to communicate data externally from the integrated circuit within which the split-gate NVM system 1100 is integrated, as desired.

As described herein, the carbon impurities introduce tensile stress into the cell structures, and this tensile stress helps maintain NVM system performance and data retention even as device geometries are reduced. For example, a carbon impurity within the charge storage layer itself provides a tensile stress that helps to maintain charge storage within the charge storage layer. A carbon impurity within the gate, such as a control gate within a split-gate structure, provides tensile stress that again facilitates charge remaining within the adjacent charge storage layer. Similarly, a carbon impurity within the drain and source regions provides a tensile stress that helps to keep charge from leaking from the charge storage layer. While the gate or charge storage layer can be implemented using carbon impurities to provide these advantages, a carbon impurity in each of these structures, as well as the drain and source regions, can be used in combination to provide increased support of data retention, if desired.

As described herein, a variety of embodiments can be implemented and different features and variations can be implemented, as desired.

One disclosed embodiment is a method for forming a non-volatile memory (NVM) cell having carbon impurities including forming a charge storage layer over a substrate and forming a gate region over the charge storage layer, where at least one of the forming steps includes introducing a carbon impurity within a silicon material as part of the forming step so that at least one of the charge storage layer and the gate region comprises silicon material having a carbon impurity. In a further embodiment, the method includes forming a drain region and a source region within the substrate and introducing a carbon impurity within a silicon material as part of the further forming step so that the drain and source regions comprise silicon material having a carbon impurity. For further embodiments, the charge storage layer is formed with silicon material having a carbon impurity.

In other embodiments, the charge storage layer is formed as a discrete charge storage layer including silicon nanocrystals, and wherein a carbon impurity is introduced into the silicon nanocrystals. In addition, the NVM cell can be a split-gate NVM cell, and the method can further include forming a select gate region over the substrate, forming the charge storage layer over the substrate and over at least a portion of the select gate region, and forming the gate region as a control gate. Still further, the carbon impurity level can be between 0.5 and 3.0 percent of the silicon material with the carbon impurity. Further, the charge storage layer is between 150 and 350 Angstroms thick.

In further embodiments, the discrete charge storage layer is formed within a dielectric layer by forming an initial oxide layer, growing an epitaxial layer of silicon nanocrystal material with the carbon impurity on top of the initial oxide layer, and forming a second oxide layer on top of the epitaxial layer. In other further embodiments, the discrete charge storage layer is formed within a dielectric layer by forming an initial oxide layer, depositing a silicon nanocrystal layer on top of the initial oxide layer, implanting carbon impurities into the silicon nanocrystal layer, and forming a second oxide layer on top of the silicon nanocrystal layer.

One further disclosed embodiment is a non-volatile memory (NVM) cell having carbon impurities including a substrate, a gate region positioned over the substrate, a charge storage layer positioned at least in part between the gate region and the substrate, a drain region formed with the substrate, and a source region formed within the substrate, where at least one of the charge storage layer and the gate region comprises silicon material having a carbon impurity. In further embodiments, the gate region includes silicon material having a carbon impurity. In other further embodiments, the charge storage layer includes silicon material having a carbon impurity. Still further, the charge storage layer and the gate region can include silicon material having a carbon impurity. In addition, the charge storage layer, the gate region, and the drain and source regions can include silicon material having a carbon impurity.

In other embodiments, the charge storage layer is a discrete charge storage layer including silicon nanocrystals having a carbon impurity. Further, the NVM cell can be a split-gate NVM cell, and can further include a select gate region positioned over the substrate, where the charge storage layer is positioned over at least a portion of the select gate region, and wherein the gate region is a control gate region. Still further, the carbon impurity level can be between 0.5 and 3.0 percent of the silicon material with the carbon impurity. Further, the charge storage layer can be between 150 and 350 Angstroms thick.

One additional disclosed embodiment is a non-volatile memory (NVM) system having NVM cells including carbon impurities including an array of non-volatile memory (NVM) cells, wordline driver circuitry coupled to the plurality of split-gate NVM cells, and column driver circuitry coupled to the plurality of split-gate NVM cells, where the array of NVM cells, the wordline driver circuitry, and the column driver circuitry are integrated within a single integrated circuit. Each NVM cell within the array further includes a substrate, a gate region positioned over the substrate, a charge storage layer positioned at least in part between the gate region and the substrate, a drain region formed with the substrate, and a source region formed within the substrate, where at least one of the charge storage layer and the gate region comprises silicon material having a carbon impurity.

In further embodiments, the charge storage layer for each NVM cell includes a discrete charge storage layer including silicon nanocrystals having a carbon impurity. In addition, the NVM cells can be split-gate NVM cells, and each NVM cell can further include a select gate region positioned over the substrate, where the charge storage layer is positioned over at least a portion of the select gate region, and wherein the gate region is a control gate region.

Unless stated otherwise, terms such as “first” and “second” are used to arbitrarily distinguish between the elements such terms describe. Thus, these terms are not necessarily intended to indicate temporal or other prioritization of such elements.

Further modifications and alternative embodiments of the described systems and methods will be apparent to those skilled in the art in view of this description. It will be recognized, therefore, that the described systems and methods are not limited by these example arrangements. It is to be understood that the forms of the systems and methods herein shown and described are to be taken as example embodiments. Various changes may be made in the implementations. Thus, although the invention is described herein with reference to specific embodiments, various modifications and changes can be made without departing from the scope of the present invention. Accordingly, the specification and figures are to be regarded in an illustrative rather than a restrictive sense, and such modifications are intended to be included within the scope of the present invention. Further, any benefits, advantages, or solutions to problems that are described herein with regard to specific embodiments are not intended to be construed as a critical, required, or essential feature or element of any or all the claims.

1. A method for forming a non-volatile memory (NVM) cell having carbon impurities, comprising:
forming a charge storage layer over a substrate; and
forming a gate region over the charge storage layer;
wherein the forming a gate region steps includes introducing a carbon impurity within a silicon material as part of the forming step so that the gate region comprises silicon material having a carbon impurity.

2. The method of claim 1, further comprising forming a drain region and a source region within the substrate and introducing a carbon impurity within a silicon material as part of the further forming step so that the drain and source regions comprise silicon material having a carbon impurity.

3. The method of claim 1, wherein the charge storage layer is also formed with silicon material having a carbon impurity.

4. The method of claim 3, wherein the charge storage layer is formed as a discrete charge storage layer including silicon nanocrystals, and wherein a carbon impurity is introduced into the silicon nanocrystals.

5. The method of claim 4, wherein the NVM cell is a split-gate NVM cell, and further comprising forming a select gate region over the substrate, forming the charge storage layer over the substrate and over at least a portion of the select gate region, and forming the gate region as a control gate.

6. The method of claim 4, wherein the carbon impurity level is between 0.5 and 3.0 percent of the silicon material with the carbon impurity.

7. The method of claim 4, wherein the charge storage layer is between 150 and 350 Angstroms thick.

8. The method of claim 4, wherein the discrete charge storage layer is formed within a dielectric layer by forming an initial oxide layer, growing an epitaxial layer of silicon nanocrystal material with the carbon impurity on top of the initial oxide layer, and forming a second oxide layer on top of the epitaxial layer.

9. The method of claim 4, wherein the discrete charge storage layer is formed within a dielectric layer by forming an initial oxide layer, depositing a silicon nanocrystal layer on top of the initial oxide layer, implanting carbon impurities into the silicon nanocrystal layer, and forming a second oxide layer on top of the silicon nanocrystal layer.

10. A non-volatile memory (NVM) cell having carbon impurities, comprising:
a substrate;
a gate region positioned over the substrate;
a charge storage layer positioned at least in part between the gate region and the substrate;
a drain region formed with the substrate; and
a source region formed within the substrate;
wherein the gate region comprises silicon material having a carbon impurity.

11. (canceled)

12. The NVM cell of claim 10, wherein the charge storage layer also comprises silicon material having a carbon impurity.

13. (canceled)

14. The NVM cell of claim 10, wherein the drain and source regions also comprise silicon material having a carbon impurity.

15. The NVM cell of claim 12, wherein the charge storage layer comprises a discrete charge storage layer including silicon nanocrystals having a carbon impurity.

16. The NVM cell of claim 15, wherein the NVM cell is a split-gate NVM cell, and further comprises a select gate region positioned over the substrate, wherein the charge storage layer is positioned over at least a portion of the select gate region, and wherein the gate region is a control gate region.

17. The NVM cell of claim 15, wherein the carbon impurity level is between 0.5 and 3.0 percent of the silicon material with the carbon impurity.

18. The NVM cell of claim 15, wherein the charge storage layer is between 150 and 350 Angstroms thick.

19. A non-volatile memory (NVM) system having NVM cells including carbon impurities, comprising:
an array of non-volatile memory (NVM) cells, each NVM cell comprising:
a substrate;
a gate region positioned over the substrate;
a charge storage layer positioned at least in part between the gate region and the substrate;
a drain region formed with the substrate; and
a source region formed within the substrate;
wherein the gate region comprises silicon material having a carbon impurity;
wordline driver circuitry coupled to the plurality of split-gate NVM cells; and
column driver circuitry coupled to the plurality of split-gate NVM cells;
wherein the array of NVM cells, the wordline driver circuitry, and the column driver circuitry are integrated within a single integrated circuit.

20. The NVM system of claim 19, wherein for each NVM cell the charge storage layer comprises a discrete charge storage layer including silicon nanocrystals having a carbon impurity.

21. The NVM system of claim 20, wherein the NVM cells comprise split-gate NVM cells, and wherein each NVM cell further comprises a select gate region positioned over the substrate, wherein the charge storage layer is positioned over at least a portion of the select gate region, and wherein the gate region is a control gate region.
